(19) United States
(12) Patent Application Publication
(10) Pub. No.: US 2023/0018751 A1
(43) Pub. Date: Jan. 19, 2023

(54) SOCKET AND INSPECTION SOCKET

(71) Applicant: Enplas Corporation, Saitama (JP)

(72) Inventor: Hiroyuki ICHIKAWA, Saitama (JP)

(73) Assignee: Enplas Corporation, Saitama (JP)

(21) Appl. No.: 17/779,626

(22) PCT Filed: Nov. 20, 2020
(86) PCT No.: PCT/JP2020/043345

§ 371 Date: May 25, 2022

(30) Foreign Application Priority Data
Nov. 29, 2019 (JP) 2019-217025

(51) Int. Cl. G01R 1/04

(52) U.S. Cl. CPC G01R 1/0433; H01R 12/88

(57) ABSTRACT

This socket comprises: an accommodation part that has a recess portion; an opening/closing part that opens/closes the recess portion; and a rotation support part that supports the opening/closing part to be rotationally movable between an opened state and a closed state. The opening/closing part has: a cover that is supported by the rotation support part; a pressing part that is provided on the first direction side of the first end and presses a electronic component in the recess portion in the closed state; a locking part that is provided on the first direction side of the pressing part and locks the cover to the accommodation part in the closed state; and a pressed part that has a pressed surface and is provided, at a position farther away from the rotation support part than the locking part, to be rotationally movable.

### TECHNICAL FIELD

The present invention relates to a socket and an inspection socket.

### BACKGROUND ART

Conventionally, for example, an integrated circuit (IC) socket is known as a socket for accommodating an electronic component such as an IC for external electrical connection of the electronic component. The IC socket is used to inspect the electrical characteristics of the electronic component during inspection of the electronic component for shipping.

Such a socket is generally provided with a configuration for pressing the electronic component in order to ensure electrical connection with the electronic component. For example, a socket disclosed in PTL 1 presses an IC package by a pusher attached to a cover member.

Further, the socket has a latch member supported by the cover member. An operator presses the cover member downward to engage the latch member with a housing when closing the socket.

The latch member maintains the closed state of the cover member with respect to the housing based on engagement with the housing. In a state where the latch member is engaged with the housing, the cover member presses a semiconductor device being an electronic component downward via the pusher.

CITATION LIST

### Patent Literature

PTL 1

Japanese Patent Application Laid-Open No. 2011-60496

### SUMMARY OF INVENTION

### Technical Problem

In the case of the socket disclosed in PTL 1 as described above, for example, when closing the socket, the operator presses the upper surface of the cover member downward at a position closer to the center of the socket than to the latch member. From the viewpoint of work efficiency, it is desirable that, when closing the socket, the force (pressing force) of the operator pressing the cover member be smaller.

It is an object of the present invention to provide a socket and an inspection socket capable of reducing a pressing force applied when the socket is closed.

### Solution to Problem

One aspect of a socket according to the present invention includes:

an accommodation part including a recess capable of accommodating an electronic component;

an opening-closing part that opens and closes an opening portion of the recess; and

a pivot supporting part that supports the opening-closing part such that the opening-closing part is capable of pivotal movement between an open state and a closed state, in which

the opening-closing part includes:

a cover that is supported at a first end portion by the pivot supporting part and that extends from the first end portion toward a first direction that is perpendicular to a pivotal axis direction of the pivotal movement and is away from the pivot supporting part in the closed state of the opening-closing part,

a pressing portion that is disposed on the first direction side of the first end portion of the cover and is configured to press the electronic component in the recess in the closed state of the opening-closing part, and

a lock portion that is disposed on the first direction side of the pressing portion and is configured to lock the cover to the accommodation part in the closed state of the opening-closing part, and

a pressed portion having a pressed surface and disposed at a position farther from the pivot supporting part than the lock portion is from the pivot supporting part, such that the pressed portion is capable of pivotal movement together with the cover.

One aspect of an inspection socket according to the present invention is

an inspection socket for use in inspection of an electrical characteristic of an electronic component, the inspection socket including:

the above-described socket; and

a contact portion disposed on a bottom of the recess and configured to be electrically connected with the electronic component in the recess.

### Advantageous Effects of Invention

According to the present invention, in a socket and an inspection socket, the pressing force applied when the socket is closed can be reduced.

### BRIEF DESCRIPTION OF DRAWINGS

FIG. 1 is a perspective view of a socket according to an embodiment of the present invention in a closed state of the socket;

FIG. 2 is a top view of the socket in the closed state of the socket illustrated in FIG. 1;

FIG. 3 is a perspective view of the socket in an open state of the socket illustrated in FIG. 1;

FIG. 4 is a sectional view taken along line A1-A1 and seen in a direction of arrows in FIG. 2;

FIG. 5 is a sectional view taken along line B1-B1 and seen in a direction of arrows in FIG. 2;

FIG. 6 is a sectional view taken along line C1-C1 and seen in a direction of arrows in FIG. 2, which illustrates the socket when the opening degree of an opening-closing part is 100° (in the open state);

FIG. 7 is a sectional view taken along line C1-C1 and seen in a direction of arrows in FIG. 2, which illustrates the socket when the opening degree of the opening-closing part is 6°;

FIG. 8 is a sectional view taken along line C1-C1 and seen in a direction of arrows in FIG. 2, which illustrates the socket when the opening degree of the opening-closing part is 0° (closed state);

FIG. 9A is a side view of Variation 1 of the cover; and

FIG. 9B is a side view of Variation 2 of the cover.

### DESCRIPTION OF EMBODIMENTS

Hereinafter, a socket according to an embodiment of the present invention will be described in detail with reference to the drawings. Although an inspection socket is described as one example of the socket, the present invention can be applied to any socket that accommodates an electronic component for external electrical connection.

### Embodiments

### Inspection Socket

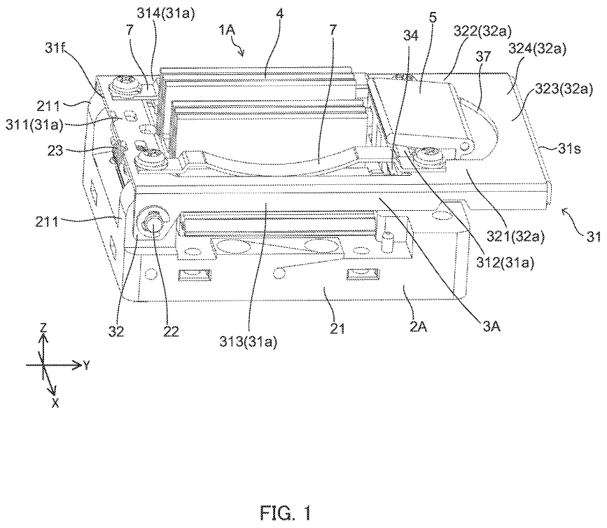

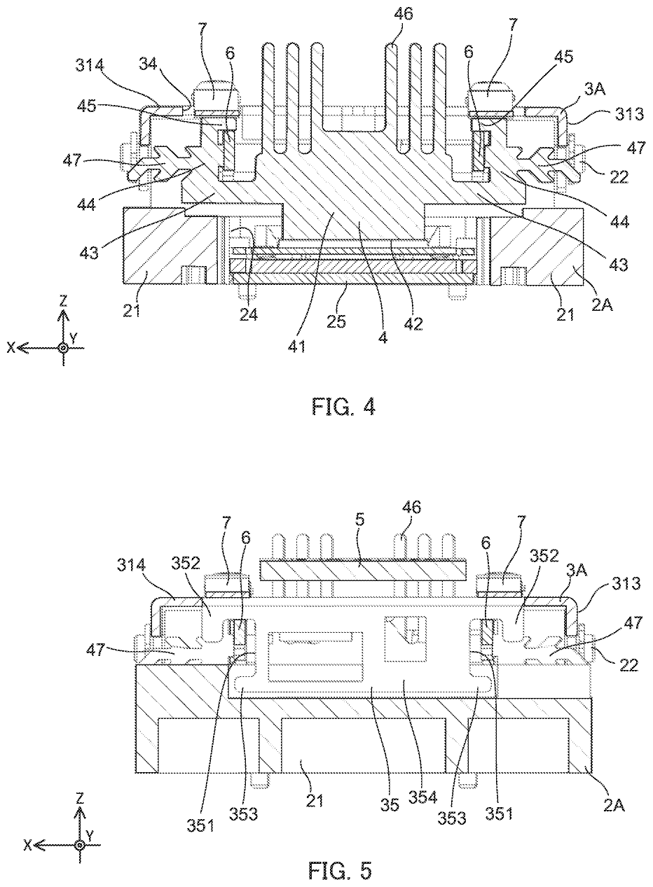

Hereinafter, referring to FIGS. 1 to 8, inspection socket 1A according to the present embodiment will be described.

In this specification, the closed position of opening-closing part 3A means the position of opening-closing part 3A illustrated in FIGS. 1, 2, and 8. In the closed position of opening-closing part 3A, the opening degree of opening-closing part 3A is 0°. The state in which opening-closing part 3A is located in the closed position is also referred to as the closed state of inspection socket 1A and opening-closing part 3A.

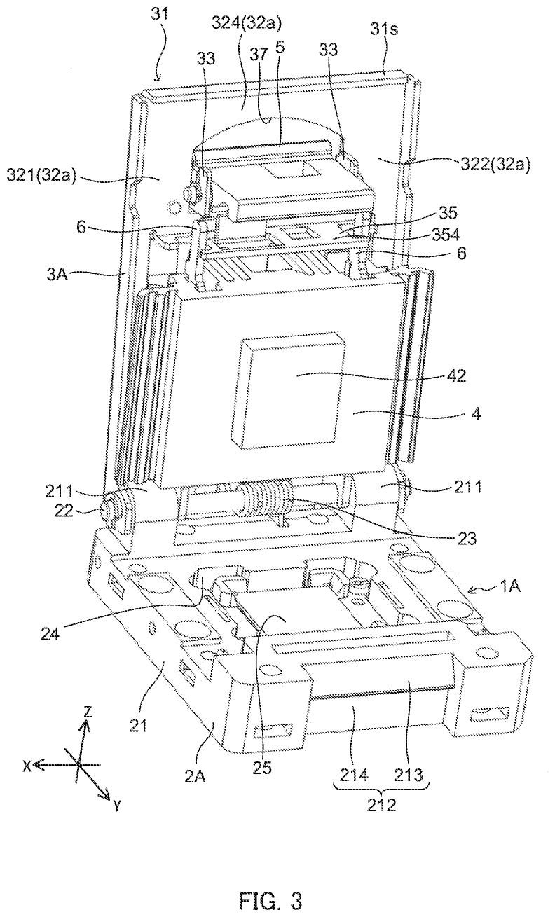

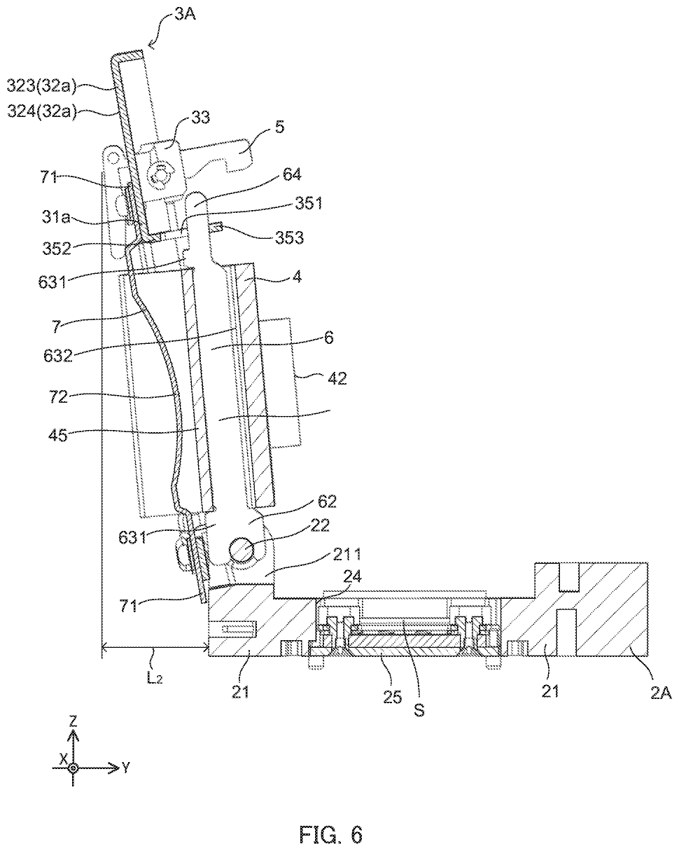

Further, in this specification, the open position of opening-closing part 3A means the position of opening-closing part 3A illustrated in FIGS. 3 and 6. In the open position of opening-closing part 3A, the opening degree of opening-closing part 3A is 100°. The state in which opening-closing part 3A is located in the open position is also referred to as the open state of inspection socket 1A and opening-closing part 3A.

The open position of opening-closing part 3A may be understood as the position of opening-closing part 3A in a state in which opening-closing part 3A is in the most open state (also referred to as the fully open state). The opening degree of opening-closing part 3A in the open position of opening-closing part 3A is a value set according to the specifications of the socket, and is not limited to 100°.

Note that, FIGS. 6 to 8 illustrate inspection socket 1A in states in which by letting the opening degree of opening-closing part 3A in the closed state be 0°, the opening degree of opening-closing part 3A is 6°, and the opening degree of opening-closing part 3A is 100°. However, the states in which the opening degree of opening-closing part 3A is 6° and 100° are examples, and the opening degree of opening-closing part 3A can be appropriately changed to other values.

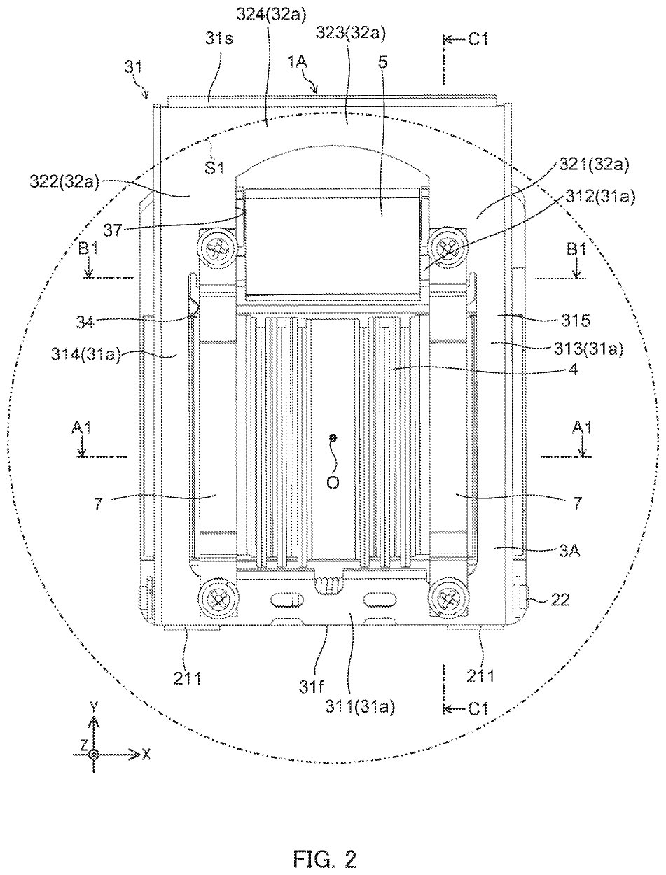

As illustrated in FIGS. 1 and 2, the present embodiment will be described using an orthogonal coordinate system (X, Y, Z). The orthogonal coordinate system (X, Y, Z) illustrated in FIGS. 1 and 2 is common to the orthogonal coordinate systems (X, Y, Z) illustrated in the other figures.

The X direction in the orthogonal coordinate system (X, Y, Z) corresponds to the lateral direction of inspection socket 1A. In addition, the Y direction in the orthogonal coordinate system (X, Y, Z) corresponds to the longitudinal direction of inspection socket 1A. In addition, the Z direction in the orthogonal coordinate system (X, Y, Z) corresponds to the height direction of inspection socket 1A.

Note that, opening-closing part 3A to be described later of inspection socket 1A pivots about a pivot supporting part (support shaft 22 to be described later). Therefore, the longitudinal direction of opening-closing part 3A may be understood as being changeable in accordance with the pivot.

The Z-direction in the orthogonal coordinate system (X, Y, Z) also corresponds to the vertical direction of inspection socket 1A. The +side in the Z direction corresponds to the upper side of inspection socket 1A, and the −side in the Z direction corresponds to the lower side of inspection socket 1A.

Inspection socket 1A is used in the inspection of the electric characteristics of below-described inspection object S (electronic component (e.g., IC package)). Inspection socket 1A in use is disposed on a wiring board (not illustrated).

Inspection socket 1A includes base 2A, opening-closing part 3A, and the like.

### Base

Base 2A corresponds to one example of an accommodation part, and includes body 21, support shaft 22, biasing member 23, recess 24, contact portion 25, and the like.

### Body

Body 21 is a frame that forms an outer peripheral portion of base 2A. Body 21 has a first end portion which is an end portion on one side in the longitudinal direction (−side in the Y direction), and a second end portion which is an end portion on the other side in the longitudinal direction (+side in the Y direction).

Body 21 includes recess 24 at a central portion. Further, body 21 includes, at the first end portion (at the end portion on the −side in the Y direction), shaft supporting portions 211.

Body 21 includes, at the second end portion (at the end portion on the +side in the Y direction), locking portion 212. In the present embodiment, body 21 has two shaft supporting portions 211 and one locking portion 212. The number of shaft supporting portions and the number of locking portions can be appropriately changed.

Shaft supporting portions 211 support support shaft 22. Locking portion 212 is engaged with latch 5 in the closed state of inspection socket 1A.

Locking portion 212 has inclined surface 213 and locking surface 214. During pivotal movement of opening-closing part 3A from the open state (open position) to the closed state (closed position), latch 5 is moved downward while making contact with inclined surface 213, and is engaged with locking surface 214.

When latch 5 is engaged with locking surface 214, opening-closing part 3A is engaged with base 2A via latch 5. When latch 5 is engaged with locking surface 214, inspection socket 1A (opening-closing part 3A) is closed.

### Support Shaft

Support shaft 22 corresponds to one example of the pivot supporting part, and is supported by shaft supporting portions 211. Specifically, both end portions of support shaft 22 are inserted respectively into two shaft supporting portions 211 described above. That is, support shaft 22 is fixed to base 2A. Support shaft 22 supports opening-closing part 3A and holding members 6 such that opening-closing part 3A and holding members 6 are capable of pivotal movement.

### Biasing Member

Biasing member 23 is held by support shaft 22. Biasing member 23 is for applying a biasing force for biasing opening-closing part 3A in the opening direction. The opening direction of opening-closing part 3A means the pivotal direction of opening-closing part 3A when opening-closing part 3A transitions from the closed state to the open state. The closing direction of opening-closing part 3A means the pivotal direction of opening-closing part 3A when opening-closing part 3A transitions from the open state to the closed state.

Specifically, biasing member 23 is a torsion coil spring, and has a first end portion, a second end portion, and a coil portion.

The first end portion of biasing member 23 is supported by base 2A. The second end portion of biasing member 23 is supported by opening-closing part 3A. Support shaft 22 is inserted in the coil portion of biasing member 23. The torsion coil spring is used as one example of biasing member 23, but any other equivalent biasing members may be used.

### Recess

Recess 24 can accommodate inspection object S inside. An opening portion of recess 24 is opened and closed by opening-closing part 3A. In the closed state of opening-closing part 3A, opening-closing part 3A presses inspection object S downward via pressing member 4.

### Contact Portion

Contact portion 25 is disposed on the bottom of recess 24, performs electrical connection with inspection object S, and performs electrical connection with the wiring board. Contact portion 25 has a plurality of contact pins (not illustrated) corresponding to the configuration of electrical terminals of inspection object S.

At the time of inspection of inspection object S, inspection object S is placed on contact portion 25 in recess 24. Then, inspection object S is pressed downward by pressing member 4. In this state, the electrical terminals of inspection object S are in contact with the contact pins, and the contact pins are in contact with the connection terminals disposed on the wiring board (not illustrated). As a result, inspection object S and the wiring board are electrically connected to each other.

### Opening-Closing Part

Opening-closing part 3A includes opening-closing-part main body 31, pressing member 4, latch 5, holding members 6, and leaf springs 7, or the like. Opening-closing part 3A is composed of opening-closing-part main body 31 and members that are assembled to opening-closing-part main body 31 and pivotally move together with opening-closing-part main body 31.

Opening-closing part 3A opens and closes the opening portion of recess 24 by pressing member 4. In the closed state of opening-closing part 3A, opening-closing part 3A is locked to base 2A based on the engagement between latch 5 and base 2A (specifically, locking portion 212 of body 21).

In the closed state of opening-closing part 3A, opening-closing part 3A presses inspection object S in recess 24 in pressing direction F by pressing member 4 (see FIG. 8).

In the present embodiment, pressing direction F is a direction perpendicular to the bottom surface of recess 24 and/or the surface of inspection object S in recess 24. By pressing inspection object S in pressing direction F, electrical connection between inspection object S and the wiring board is reliably made.

Pressing direction F does not have to be the direction perpendicular to the surface of inspection object S and/or the bottom surface of recess 24. Pressing direction F may be any direction as long as inspection object S is not moved on the bottom surface of recess 24 based on the pressing force in pressing direction F.

### Opening-Closing-Part Main Body

Opening-closing-part main body 31 is a frame forming the outer peripheral portion of opening-closing part 3A. In the closed state of opening-closing part 3A, opening-closing-part main body 31 covers the surface of base 2A on the side in which recess 24 is disposed. Hereinafter, the pivotal axis direction means the axial direction of support shaft 22 that is the pivotal axis of opening-closing-part main body 31 (the direction of the central axis). In the present embodiment, the pivotal axis direction corresponds to the X direction.

In the closed state of opening-closing part 3A, opening-closing-part main body 31 is locked to base 2A based on the engagement between latch 5 and base 2A.

Opening-closing-part main body 31 includes cover 31a, extension portion 32a, supported portions 32, first opening portion 34, second opening portion 37, latch support plates 33, and holding plate 35, and the like.

Further, opening-closing-part main body 31 includes first end portion 31f and second end portion 31s. First end portion 31f and second end portion 31s are both end portions of opening-closing-part main body 31 in a direction (Y direction) perpendicular to the pivotal axis direction of support shaft 22 that is the pivotal axis.

Note that, with respect to opening-closing-part main body 31 and opening-closing part 3A, the direction perpendicular to the pivotal axis direction of support shaft 22 is referred to as the longitudinal direction of opening-closing part 3A and the longitudinal direction of opening-closing-part main body 31. In the closed state of opening-closing part 3A, the longitudinal direction of opening-closing part 3A and the longitudinal direction of opening-closing-part main body 31 coincide with the longitudinal direction (Y direction) of inspection socket 1A.

Hereinafter, in the description of opening-closing part 3A and the members constituting opening-closing part 3A, the longitudinal direction of opening-closing part 3A and the longitudinal direction of opening-closing-part main body 31 are simply referred to as the longitudinal direction.

In the closed state of inspection socket 1A, opening-closing-part main body 31 extends from first end portion 31f to second end portion 31s in the longitudinal direction. In this specification, in the closed state of opening-closing part 3A, the direction from first end portion 31f to second end portion 31s is referred to as a first direction.

In other words, the first direction is a direction that is perpendicular to the pivotal axis direction of the pivotal movement of opening-closing-part main body 31 (X direction) and that is away from the pivot supporting part (support shaft 22) in the closed state of opening-closing part 3A. The second direction is a direction opposite to the first direction.

As illustrated in FIG. 8, in the closed state of inspection socket 1A, the first direction coincides with a direction extending from one side in the longitudinal direction (the −side in the Y direction) of inspection socket 1A toward the other side in the longitudinal direction (the +side in the Y direction).

### Cover

Cover 31a has first frame element 311, second frame element 312, third frame element 313, and fourth frame element 314 connected to one another in a rectangular frame shape.

First frame element 311 and second frame element 312 extend in the pivotal axis direction (X direction) and are parallel to each other. First frame element 311 is disposed at a portion corresponding to first end portion 31f of opening-closing-part main body 31. Second frame element 312 is disposed on the first direction side of first frame element 311 in the longitudinal direction.

Third frame element 313 longitudinally connects together a first end portion (end portion on the +side in the X direction) of first frame element 311 and a first end portion (end portion on the +side in the X direction) of second frame element 312. A first end portion of third frame element 313 in the longitudinal direction is connected to the first end portion of first frame element 311. A second end portion of third frame element 313 in the longitudinal direction is connected to the first end portion of second frame element 312.

Fourth frame element 314 longitudinally connects together a second end portion of first frame element 311 (end portion on the −side in the X direction) and a second end portion of second frame element 312 (end portion on the −side in the X direction). A first end portion of fourth frame element 314 in the longitudinal direction is connected to the second end portion of first frame element 311. A second end portion of fourth frame element 314 in the longitudinal direction is connected to the second end portion of second frame element 312.

Third frame element 313 and fourth frame element 314 face vertical wall portions 44 respectively in the pivotal axis direction (X direction), the vertical wall portions being the outer peripheral portion of pressing member 4 (described later). Third frame element 313 and fourth frame element 314 are disposed to form an air gap between the frame elements and base 2A in the closed state of opening-closing part 3A.

### Extension Portion

As illustrated in FIGS. 1 and 2, extension portion 32a extends from cover 31a in the first direction (on the +side in the Y direction). In the present embodiment, extension portion 32a is integrally formed with cover 31a. However, extension portion 32a may be a member separate from cover 31a and may be joined to cover 31a by a fastening member. The fastening member may be, for example, a fastening component such as a bolt or a pin, or welding.

Specifically, extension portion 32a includes first arm portion 321, second arm portion 322, and pressed portion 323.

### First Arm Portion

First arm portion 321 corresponds to one example of an arm portion, and extends in the longitudinal direction. First arm portion 321 has a first end portion and a second end portion in the longitudinal direction.

The first end portion of first arm portion 321 in the longitudinal direction is connected to third frame element 313 of cover 31a. Specifically, first arm portion 321 extends in the first direction from the second end portion of third frame element 313 in the longitudinal direction. In the present embodiment, first arm portion 321 is a member parallel to the longitudinal direction over the entire length.

### Second Arm Portion

Second arm portion 322 corresponds to one example of the arm portion, and extends in the longitudinal direction in a state of being parallel to first arm portion 321. Second arm portion 322 has a first end portion and a second end portion in the longitudinal direction.

The first end portion of second arm portion 322 in the longitudinal direction is connected to fourth frame element 314 of cover 31a. Specifically, second arm portion 322 extends in the first direction from the second end portion of fourth frame element 314 in the longitudinal direction. In the present embodiment, second arm portion 322 is a member parallel to the longitudinal direction over the entire length.

### Pressed Portion Pressed portion 323 is a member parallel to the pivotal axis direction (X direction).

In the pivotal axis direction (X direction), pressed portion 323 connects together the second end portion of first arm portion 321 in the longitudinal direction and the second end portion of second arm portion 322 in the longitudinal direction.

Pressed portion 323 is disposed on the first direction side of latch 5 in the longitudinal direction. Pressed portion 323 protrudes beyond base 2A in the first direction. Therefore, in the closed state of inspection socket 1A, pressed portion 323 does not face base 2A in the vertical direction.

In the closed state of opening-closing part 3A (when opening-closing part 3A is located at the closed position), opening-closing part 3A protrudes in the first direction from base 2A by distance L₁ (see FIG. 8). On the other hand, in the open state of opening-closing part 3A (when opening-closing part 3A is located at the open position), opening-closing part 3A protrudes from base 2A by distance L₂ (see FIG. 6) in the second direction which is the direction opposite to the first direction. For the present embodiment, distance L₁ is less than or equal to distance L₂ (L₁<L₂).

With such a configuration, when the inspection is performed with a plurality of inspection sockets 1A arranged in the first direction of opening-closing part 3A, it is possible to suppress interference between inspection sockets 1A adjacent to each other in the longitudinal direction.

In the present embodiment, pressed portion 323 is integrally molded with cover 31a via first arm portion 321 and second arm portion 322. Therefore, pressed portion 323 is capable of pivotal movement together with cover 31a.

Pressed portion 323 has pressed surface 324 that is a flat surface facing upward. Pressed surface 324 is a portion to be pressed when closing opening-closing part 3A. In other words, pressed surface 324 is a portion that is pressed downward when latch 5 is brought into engagement with base 2A (specifically, with locking portion 212 of body 21).

The pressed surface is not limited to a flat surface. The pressed surface may be, for example, a roughened surface or a curved surface. Further, the orientation of the pressed surface is not limited to the upward direction. That is, the normal direction of a normal to the pressed surface is not limited to the direction parallel to the vertical direction (Z direction), and may be inclined with respect to the vertical direction (Z direction).

Further, in the case of the present embodiment, pressed portion 323 is disposed on the first direction side of latch 5 in the longitudinal direction. However, the position of the pressed portion with respect to the latch is not limited to the case of the present embodiment. The pressed portion may be disposed anywhere as long as the pressing portion is disposed at a position farther from support shaft 22 than the latch is.

In case that the operation of closing opening-closing part 3A is performed manually by an operator, pressed surface 324 is pressed downward by the operator's hand. Further, in case that the operation of closing opening-closing part 3A is mechanically performed by a device, pressed surface 324 is pressed downward by a part of the device (e.g., by a pressing portion of the device).

In the case of the present embodiment, pressed surface 324 is coplanar with the upper surface of cover 31a. Further, in the case of the present embodiment, circle S (a circle indicated by a double-dot dashed line in FIG. 2) centered on a center line that passes through pressing center O (see FIG. 2) of a press of inspection object S by pressing member 4 and that is parallel to the vertical direction (Z direction) continuously passes on pressed surface 324 from the first end portion to the second end portion of pressed surface 324 in the pivotal axis direction.

With such a configuration, the pressing force applied to pressed surface 324 by the operator to close opening-closing part 3A is smoothed over entire pressed surface 324. Therefore, the pressing force applied by the operator does not differ greatly depending on positions on pressed surface 324. Note that, in the above description, although pressed portion 323 is understood as one example of the pressed portion, extension portion 32a may be understood as one example of the pressed portion.

### Variation 1 of Cover

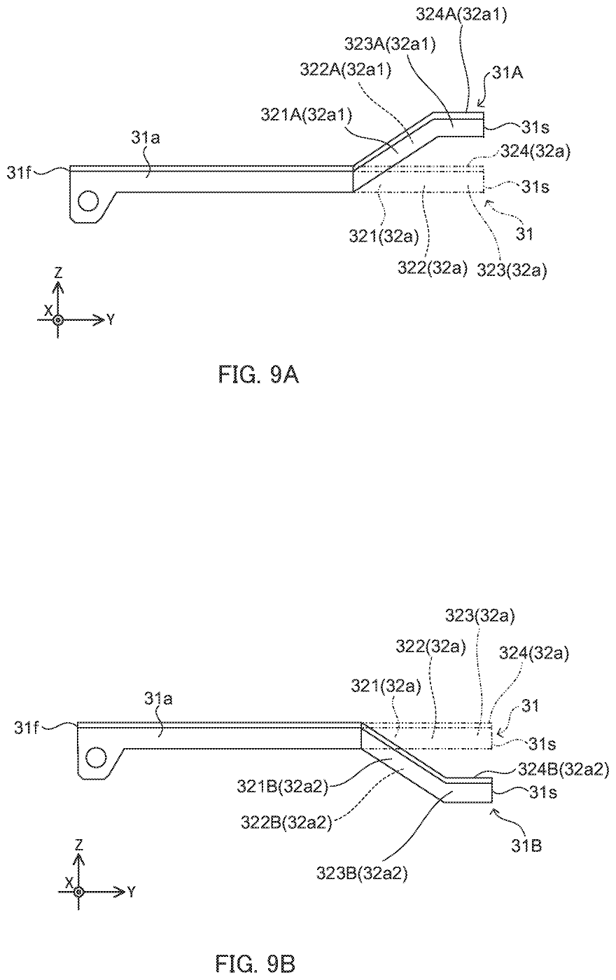

FIG. 9A is a side view of opening-closing-part main body 31A according to Variation 1 (a side view of opening-closing-part main body 31A as viewed from the +side in the X direction). In FIG. 9A, the solid line illustrates extension portion 32a1 of opening-closing-part main body 31A of the present variation. FIG. 9A illustrates extension portion 32a of opening-closing-part main body 31 according to the above-described embodiment by a double-dot dashed line. The configuration of cover 31a is the same as that of the above-described embodiment.

In the present variation, pressed portion 323A of extension portion 32a1 is provided above pressed portion 323 of extension portion 32a in the above-described embodiment (on the +side of pressed portion 323 in the Z direction).

Thus, first arm portion 321A and second arm portion 322A of extension portion 32a are inclined in the upward direction toward the first direction in the longitudinal direction.

In the pivotal axis direction, pressed portion 323A connects together a second end portion of first arm portion 321A in the longitudinal direction and a second end portion of second arm portion 322A in the longitudinal direction.

Also in the present variation, pressed portion 323A is disposed on the first direction side of latch 5. Also in the present variation, pressed portion 323A is integrally molded with cover 31a. Therefore, pressed portion 323A is capable of pivotal movement together with cover 31a.

Pressed portion 323A has pressed surface 324A that is a flat surface facing upward. Pressed surface 324A is located above the upper surface of cover 31a. The rest of the structure of pressed portion 323A is the same as the structure of pressed portion 323 in the embodiment described above.

According to the configuration of the extension portion according to Variation 1, the position of pressed surface 324A can be disposed at a position farther from pressing center O of a press of inspection object S by pressing member 4 than pressed surface 324 in Embodiment 1 described above is from the pressing center. Consequently, the downward force to be applied to pressed surface 324A when closing opening-closing part 3A is smaller.

In the case of this variation, pressed portion 323A is inclined by a predetermined angle with respect to first arm portion 321A and second arm portion 322A. However, although not illustrated, the pressed portion may be parallel to first arm portion 321A and second arm portion 322A. In this case, the direction of the pressed surface (normal direction of the pressing surface) is inclined with respect to the vertical direction.

### Variation 2 of Cover

FIG. 9B is a side view of opening-closing-part main body 31B according to Variation 2. FIG. 9B illustrates extension portion 32a2 of opening-closing-part main body 31B of the present variation by the solid line. Also, in FIG. 9B, extension portion 32a of opening-closing-part main body 31 according to the above-described embodiment is illustrated by a double-dot dashed line. The configuration of cover 31a is the same as that of the above-described embodiment.

In the present variation, pressed portion 323B of extension portion 32a2 is disposed below pressed portion 323 of extension portion 32a in the above-described embodiment (on the −side in the Z direction).

Thus, first arm portion 321B and second arm portion 322B of extension portion 32a are inclined in the downward direction toward the first direction in the longitudinal direction.

In the pivotal axis direction, pressed portion 323B connects together a second end portion of first arm portion 321B in the longitudinal direction, and a second end portion of second arm portion 322B in the longitudinal direction.

Also in the present variation, pressed portion 323B is disposed on the first direction side of latch 5. Also in the present variation, pressed portion 323B is integrally molded with cover 31a. Therefore, pressed portion 323B is capable of pivotal movement together with cover 31a.

Pressed portion 323B is a flat surface facing upward, and has pressed surface 324B. Pressed surface 324B is located below the upper surface of cover 31a. The rest of the structure of pressed portion 323B is the same as the structure of pressed portion 323 in the embodiment described above.

According to the configuration of the extension portion according to Variation 2, the position of pressed surface 324B can be disposed at a position farther from pressing center O of a press of inspection object S by pressing member 4 than pressed surface 324 of Embodiment 1 described above is from the pressing center. Consequently, the downward force to be applied to pressed surface 324B when closing opening-closing part 3A is smaller.

Further, above-mentioned Variations 1 and 2 have been described in relation to the aspect in which pressed surface 324 is a flat surface facing upward, but the present invention is not limited to this, and pressed surface 324 does not have to face upward. For example, in Variation 1 or 2, pressed surface 324 does not have to be bent, and first arm portion 321B and second arm portion 322B may have the same angles as pressed surface 324. Further, pressed surface 324 only needs to be disposed at a position farther from the pivot supporting part than latch 5 is from the pivot supporting part. For example, pressing surface 324 may be directly above latch 5 as long as it satisfies the positional relationship described above.

### Supported Portion

Supported portions 32 are formed at first end portion 31f of opening-closing-part main body 31 (specifically, cover 31a) (the end portion on the support shaft 22 side). In the case of the present embodiment, supported portions 32 are disposed on both end portions of first end portion 31f of opening-closing-part main body 31 in the pivotal axis direction (X direction).

Each of supported portions 32 includes a round support shaft hole. Support shaft 22 is inserted in the support shaft holes. Supported portion 32 is supported by support shaft 22 and the support shaft hole pivotally with respect to base 2A. Therefore, opening-closing part 3A pivots about support shaft 22 to be opened and closed, and opens and closes with respect to base 2A.

### First Opening Portion

First opening portion 34 is provided in a portion surrounded by first frame element 311, second frame element 312, third frame element 313, and fourth frame element 314 of cover 31a. First opening portion 34 is an opening portion which opens upward and downward. Pressing member 4 and holding members 6 are disposed in first opening portion 34.

### Second Opening Portion

Second opening portion 37 is provided in a portion surrounded by fourth frame element 314 of cover 31a, first arm portion 321, second arm portion 322, and pressed portion 323 of extension portion 32a. Second opening portion 37 is an opening portion which opens upward and downward.

Second opening portion 37 is provided in opening-closing-part main body 31 on the first direction side from first opening portion 34. Latch 5 is disposed in second opening portion 37. As is understood, latch 5 is disposed in opening-closing-part main body 31 on the first direction side of pressing member 4.

### Latch Support Plate

Latch support plates 33 are a pair of flat plates extending in a direction perpendicular to upper surface 314 of opening-closing-part main body 31 at positions corresponding to second opening portion 37 in opening-closing-part main body 31. The pair of latch support plates 33 support latch 5 such that a pivot is possible.

### Holding Plate

Holding plate 35 holds held portions 64 of holding members 6 such that the held portions are relatively movable in the opening-closing direction of opening-closing part 3A within the range of holding grooves 351 (described later). Holding plate 35 is second end portion 31s of opening-closing-part main body 31, and has the shape of a flat plate extending in a direction perpendicular to upper surface 314 of opening-closing-part main body 31.

Specifically, as illustrated in FIG. 5, holding plate 35 includes base portion 354, and holding grooves 351 formed in both ends of base portion 354 in the pivotal axis direction.

Holding grooves 351 are defined by first holding portions 352 formed on the opening-closing-part main body 31 side of the end portion of base portion 354 in the pivotal axis direction, and second holding portions 353 formed on the body 21 side of the end portion of base portion 354 in the pivotal axis direction.

Each of first holding portions 352 is L-shaped and extends outward in the pivotal axis direction from the end portion of base portion 354 in the pivotal axis direction. Specifically, each of first holding portions 352 includes a first arm portion and a second arm portion.

The first arm portion extends outward in the pivotal axis direction toward a second end portion (outer end portion in the pivotal axis direction) from a first end portion connected to the end portion of base portion 354 in the pivotal axis direction (inner end portion in the pivotal axis direction). The second arm portion extends from the second end portion of the first arm portion toward body 21.

Second holding portion 353 extends outward in the pivotal axis direction from the end portion of base portion 354 in the pivotal axis direction. A space between first holding portion 352 and second holding portion 353 serves as holding groove 351. Held portion 64 of each of holding members 6 is inserted in this holding groove 351.

In this specification, the “outer side” or “outside” in the pivotal axis direction means a direction that is parallel to the pivotal axis direction from a predetermined position serving as a base point and that is away from the central portion of inspection socket 1A. On the other hand, in the present specification, the “inner side” or “inside” in the pivotal axis direction means a direction that is parallel to the pivotal axis direction from a predetermined position serving as a base point and that is toward the central portion of the direction and inspection socket 1A.

### Pressing Member

Pressing member 4 corresponds to one example of a pressing portion, and includes pressing-member main body 41, pressing surface 42, lower flanges 43, vertical wall portions 44, upper flanges 45 (longitudinal portion), upper fins 46, and side fins 47 (pressing member protrusion), and the like.

Pressing member 4 is disposed in opening-closing-part main body 31 on the first direction side of first end portion 31f of opening-closing-part main body 31. Specifically, pressing member 4 is held in first opening portion 34 in opening-closing-part main body 31 by holding members 6.

Pressing-member main body 41 is a main body portion of pressing member 4. Pressing surface 42 is formed by the bottom of pressing-member main body 41. In addition, in the closed state of opening-closing part 3A, pressing surface 42 presses inspection object S placed on contact portion 25 in pressing direction F.

Pressed by pressing member 4, inspection object S is reliably electrically connected with the wiring board via contact portion 25.

Pressing-member main body 41 includes, at both end portions in the pivotal axis direction, lower flanges 43, vertical wall portions 44, and upper flanges 45. Lower flanges 43, vertical wall portions 44, and upper flanges 45 are formed to extend in the longitudinal direction along holding members 6.

Lower flanges 43 protrude outward in the pivotal axis direction from the end portions of pressing-member main body 41 in the pivotal axis direction.

Vertical wall portions 44 are formed upright on the outer edges of lower flanges 43. Upper flanges 45 are formed to protrude inward in the pivotal axis direction from vertical wall portions 44. That is, lower flanges 43, vertical wall portions 44, and upper flanges 45 as seen in the cross-section taken in a plane perpendicular to the longitudinal direction of opening-closing part 3A form a U shape turned sideways.

In addition, the lower surface of each of upper flanges 45 extends in the longitudinal direction. Upper flange 45 is disposed to face supporting portion 63 such that the upper flange functions as a portion supported by supporting portion 63.

Further, each of vertical wall portions 44 and pressing-member main body 41 facing vertical wall portion 44 are disposed to face each other in the pivotal axis direction, with holding member 6 being interposed in between. Vertical wall portion 44 and pressing-member main body 41 function as a movement restricting portion for restricting movement of holding member 6 in the pivotal axis direction.

Holding member 6 is surrounded by vertical wall portion 44 and pressing-member main body 41. Thus, coming off of holding member 6 outward in the pivotal axis direction outside is suppressed. Further, since the width between vertical wall portion 44 and pressing-member main body 41 can be narrowed, it is possible to suppress an increase in lateral width of inspection socket 1A.

Like lower flanges 43, vertical wall portions 44, and upper flanges 45, upper fins 46 and side fins 47 are also formed to extend in the longitudinal direction. Upper fins 46 extend upward from the upper portion of pressing-member main body 41. Upper fins 46 protrude from upper surface 314 of opening-closing-part main body 31 to the outside of inspection socket 1A.

Side fins 47 also extend outward in the pivotal axis direction from the end portions of vertical wall portions 44. Side fins 47 protrude from vertical wall portions 44 through the air gap between, on one hand, third frame element 313 and fourth frame element 314 of opening-closing-part main body 31 and, on the other hand, base 2A to the outside of inspection socket 1A.

Pressing member 4 functions as a heat dissipation member that makes contact with inspection object S, absorbs heat from inspection object S, and dissipates the absorbed heat from a plurality of upper fins 46 and side fins 47 to the surroundings to maintain inspection object S at a predetermined temperature.

Further, in the present embodiment, opening-closing-part main body 31 does not need to be high. Thus, upper fins 46 and side fins 47 are exposed, or upper fins 46 and side fins 47 are formed to protrude to the outside of opening-closing-part main body 31. Accordingly, it is possible to further improve the heat dissipation performance.

In the case of the present embodiment, pressing member 4 also serves as the heat dissipation member. Thus, although a plurality of upper fins 46 and side fins 47 are formed, upper fins 46 and side fins 47 may be omitted in case that the function as the heat dissipation member is not required.

Further, by using holding member 6, it becomes unnecessary to process a hole for the shaft in pressing member 4. Thus, it becomes possible also to mold pressing member 4 by extrusion. Consequently, the manufacturing cost of pressing member 4 is reduced, and also the degree of freedom of processing increases.

### Latch

Latch 5 corresponds to one example of a lock portion, and is disposed in second opening portion 37 in opening-closing-part main body 31. When opening-closing part 3A is closed, latch 5 is pushed toward base 2A to lock opening-closing part 3A to base 2A.

Latch 5 is pivotally attached between the pair of latch support plates 33, and is locked to locking portion 212 of base 2A in the closed state of opening-closing part 3A. At this time, latch 5 is biased by the biasing member such as a torsion coil spring (not illustrated) disposed on latch 5 such that the locked state to locking portion 212 is maintained.

### Holding Member

As illustrated in FIGS. 6 to 8, each of holding members 6 includes holding-member main body 61, supported portion 62 (notch), supporting portion 63 (pressing member supporting part), held portion 64 (extension portion), and the like.

Holding member 6 is disposed between opening-closing-part main body 31 and pressing member 4. Therefore, holding member 6 holds pressing member 4 such that pressing member 4 is capable of pivotal movement together with opening-closing-part main body 31.

Holding member 6 holds pressing member 4 movably such that pressing surface 42 is along the surface of inspection object S when pressing member 4 makes contact with inspection object S.

In the present embodiment, two holding members 6 are disposed, but the number of holding members and the arrangement position in the axial direction can be appropriately changed. When changing the number and arrangement position of holding members, the number and arrangement position of lower flanges 43, vertical wall portions 44, and upper flanges 45 of pressing member 4 may be changed so as to correspond to the change in number and arrangement position of holding members.

Holding-member main body 61 is a plate-like member extending in the longitudinal direction. The side surface of holding-member main body 61 faces vertical wall portion 44.

Supported portion 62 is disposed at the base end portion of holding-member main body 61. The base end portion of holding-member main body 61 is an end portion on the side corresponding to first end portion 31f of opening-closing-part main body 31 in the longitudinal direction.

Supported portion 62 has a cutout shape allowing support shaft 22 to be detachably fitted therein, and for example, is formed in a U-shape or C-shape. Supported portion 62 is rotatably supported by support shaft 22.

Since supported portion 62 is formed in such a shape, it is possible to easily replace holding member 6 with another holding member with a different size depending on the shape of inspection object S (thickness, etc.) when changing the holding member.

Supporting portion 63 is a portion for supporting upper flange 45 of pressing member 4. Supporting portion 63 is disposed between supported portion 62 and held portion 64 in holding-member main body 61.

When pressing member 4 makes contact with inspection object S due to the pivotal movement of opening-closing part 3A in the closing direction, pressing member 4 receives a reaction force from inspection object S. At this time, supporting portion 63 supports upper flange 45 from the side of the closed position in order that at least a portion of the supporting part can be spaced from upper flange 45 by the reaction force associated with the contact.

Further, supporting portion 63 includes, at both sides in the longitudinal direction, protrusions 631 (holding member protrusions) protruding on the side of the open position. Supporting portion 63 and protrusions 631 define accommodation groove 632 for accommodating upper flange 45.

Protrusions 631 guide pressing member 4 such that upper flange 45 is accommodated in accommodation groove 632, and regulates the position of upper flange 45 to position pressing member 4. With such a configuration, the movement of pressing member 4 in the longitudinal direction is restricted.

Held portion 64 is provided at the tip portion of holding-member main body 61. The tip portion of holding-member main body 61 is an end portion on the side corresponding to second end portion 31s of opening-closing-part main body 31 in the longitudinal direction.

Held portion 64 extends from supporting portion 63 in the first direction. Held portion 64 is inserted into holding groove 351 of holding plate 35. Since held portion 64 is movable within the range inside holding groove 351, holding member 6 can pivot with respect to opening-closing part 3A within the range of angles corresponding to the range inside holding groove 351.

Since in the socket as illustrated in PTL 1, the pusher is attached by the shaft inserted in the side surface of the cover member in the horizontal direction from an insertion port, the side surface of the cover member needs some height.

In contrast, in the present embodiment, pressing member 4 is held by holding member 6 extending in the longitudinal direction. Thus, it is unnecessary that a conventional insertion hole is formed in side surface portion 313 of opening-closing-part main body 31, and the height is not required. That is, the height of opening-closing part 3A, and thus, of inspection socket 1A can be reduced.

In addition, in the present embodiment, holding member 6 is disposed between opening-closing-part main body 31 and pressing member 4. Thus, the direction of pressing member 4 can be adjusted such that pressing member 4 can be separated from holding member 6 and pressing surface 42 is parallel to the surface of inspection object S at the time of contact with inspection object S.

In addition, holding member 6 has a flat plate shape, and can thus be easily manufactured by press working, and the shape thereof can be easily changed. For example, when the distance by which pressing member 4 is pressed is changed or pressing member 4 is tilted and pressed in accordance with the shape of inspection object S, the positions and/or the tilts of held portion 64, accommodation groove 632, and/or the like with respect to opening-closing part 3A in the closed position may be changed.

### Leaf Spring

Each of leaf springs 7 is a plate-like member that extends in the longitudinal direction as illustrated in FIGS. 2 and 6 to 8. Leaf spring 7 extends in the longitudinal direction, and includes fixation portion 71, pressing portion 72, and the like.

Leaf spring 7 includes fixation portions 71 at both ends. Each of fixation portions 71 is screwed to upper surface 314 of opening-closing-part main body 31. In this manner, leaf spring 7 is fixed to opening-closing part 3A.

Leaf spring 7 presses the upper surface of upper flange 45 in pressing direction F in case that upper flange 45 of pressing member 4 is spaced apart from supporting portion 63 of holding member 6 and comes into contact with leaf spring 7. Such a leaf spring 7 functions as a flange pressing part.

Leaf spring 7 elastically deforms based on the force applied from upper flange 45 spaced from supporting portion 63, and presses the upper surface of upper flange 45 in the closing direction by the restoring force caused by the elastic deformation.

Pressing portion 72 is a portion disposed in the central portion of leaf spring 7 and exerting a pressing force on pressing member 4. Pressing portion 72 is curved so as to have a shape convex toward the upper flange 45 side.

By the curved shape of pressing portion 72, a relatively large gap is present between both end portions of upper flange 45 in the longitudinal direction and supporting portion 63 before latch 5 and locking portion 212 is engaged with each other (also referred to as “state before latching of opening-closing part 3A”).

Further, in a state where latch 5 and locking portion 212 are engaged with each other (also referred to as “latched state of opening-closing part 3A”), pressing portion 72 presses upper flange 45 downward.

In the conventional socket, the pressing member is pressed by utilizing the bendability of the cover or the like, pressed with an elastic member such as a coil spring, or pressed with a cam. Therefore, there have been problems such as: the number of parts is large; the pressing setting of the pressing member cannot be easily changed, the pressing member is unintentionally inclined, and an inspection object is rubbed.

In contrast, in the present embodiment, pressing member 4 is pressed using leaf spring 7. Therefore, by changing the material and thickness of leaf spring 7, it is possible to set the pressing condition only by deflection of leaf spring 7. Therefore, the pressing force against pressing member 4 can be easily changed to the desired pressing force. Also, leaf spring 7 as described above can be easily manufactured. Also, leaf spring 7 can be easily positioned with respect to holding member 6.

Further, leaf spring 7 is disposed along upper flange 45 of pressing member 4 in the longitudinal direction. It is thus possible to save space. Further, leaf spring 7 does not need to be high relatively to a coil spring or the like. Thus, the height of opening-closing part 3A and thus of inspection socket 1A can be reduced.

Further, pressing portion 72 and supporting portion 63 are disposed close to each other in the opening-closing direction of opening-closing part 3A, with upper flange 45 of pressing member 4 being interposed in between. Thus, the height of opening-closing part 3A and thus of inspection socket 1A can be reduced.

### Operation of Inspection Socket

The operation of holding member 6 in inspection socket 1A described above will be described with reference to FIGS. 6 to 8.

In the following description of inspection socket 1A, an operator is a subject of operation of closing opening-closing part 3A. However, the subject of the operation of closing opening-closing part 3A may be a device. When the subject of the operation of closing opening-closing part 3A is the device, the term “operator” in the following description may be appropriately replaced with the “device.”

Referring to FIG. 6, inspection socket 1A when the opening degree of opening-closing part 3A is 100° will be described. As described above, leaf spring 7 is fixed to opening-closing part 3A. In addition, as described above, holding member 6 can pivot within the range of angles corresponding to the range inside holding groove 351, and when the opening degree of opening-closing part 3A is 100°, the holding member can pivot with respect to opening-closing-part main body 31.

At this point, pressing portion 72 of leaf spring 7 does not press upper flange 45 of pressing member 4. Also, pressing member 4 is not in contact with inspection object S. Therefore, pressing member 4 in which upper flange 45 is disposed between holding member 6 and leaf spring 7 is in a state in which the pressing member can be spaced apart from holding member 6, but no force other than gravity is applied.

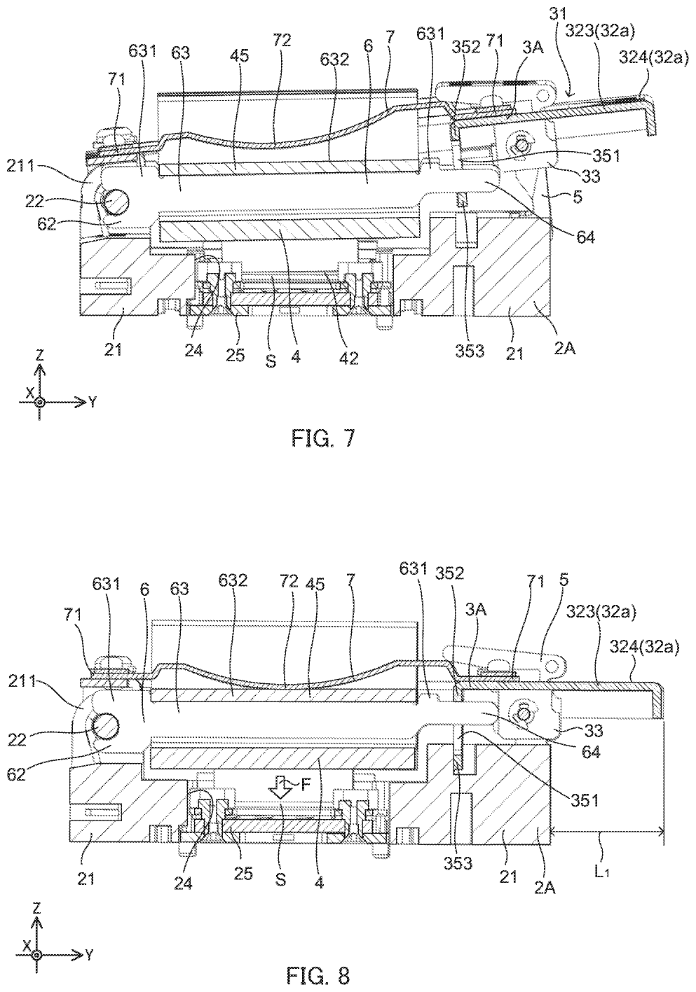

The operator causes opening-closing part 3A to pivot by the operator's hand from the open state of opening-closing part 3A illustrated in FIG. 6. As a result, the state of inspection socket 1A transitions to the state illustrated in FIG. 7.

Note that, a state between the open state (the state illustrated in FIG. 6) and the closed state of opening-closing part 3A (inspection socket 1A) (the state illustrated in FIG. 8) is referred to as an intermediate state of opening-closing part 3A (inspection socket 1A). The state of opening-closing part 3A and inspection socket 1A illustrated in FIG. 6 may be regarded as the intermediate state.

Referring to FIG. 7, inspection socket 1A when the opening degree of opening-closing part 3A is 6° will be described. When opening-closing part 3A is moved in the closing direction, the tip portion of latch 5 comes into contact with inclined surface 213 of locking portion 212 illustrated in FIG. 3 when the opening degree of opening-closing part 3A is 6°.

Held portion 64 of holding member 6 is held in holding groove 351. Further, upper flange 45 of pressing member 4 is disposed between holding member 6 and leaf spring 7. Therefore, holding member 6 and pressing member 4 are moved in the closing direction together with opening-closing part 3A.

In the case where the opening degree of opening-closing part 3A is 6°, pressing member 4 is in the state in which the pressing member can be separated from holding member 6 and in the state in which the pressing member is not in contact with inspection object S as in the case in which the opening degree of opening-closing part 3A is 100°.

Note that, pressing member 4 is movable between holding member 6 and leaf spring 7. Therefore, with decreasing opening degree of opening-closing part 3A, upper flange 45 is accommodated inside accommodation groove 632 based on the weight of pressing member 4.

When opening-closing part 3A further moves in the closing direction, a part of pressing surface 42 of pressing member 4 comes into contact with inspection object S. However, until upper flange 45 is pressed by pressing portion 72, pressing member 4 is in the state in which the pressing member can be spaced apart from holding member 6, as in the case where the opening degree of opening-closing part 3A is 6°.

Therefore, when a part of pressing surface 42 is in contact with inspection object S, pressing member 4 is inclined due to the reaction force associated with this contact such that pressing surface 42 of pressing member 4 becomes parallel to the surface of inspection object S.

At this time, upper flange 45 is in the state of being accommodated inside accommodation groove 632. Therefore, pressing member 4 is inclined such that pressing surface 42 is parallel to the surface of inspection object S, in the state where protrusions 631 prevent upper flange 45 from coming off accommodation groove 632.

Next to the state illustrated in FIG. 7, the operator presses pressed surface 324 of opening-closing part 3A downward by the operator's hand. Then, latch 5 is engaged with locking portion 212, and opening-closing part 3A is locked to base 2A via latch 5. Consequently, the state of inspection socket 1A transitions to the closed state illustrated in FIG. 8.

Referring to FIG. 8, inspection socket 1A when the opening degree of opening-closing part 3A is 0° will be described. When opening-closing part 3A is moved further in the closing direction by the operator pressing pressed surface 324, the opening degree of opening-closing part 3A becomes 0°, and latch 5 is brought into a locked state in which the latch is locked to locking surface 214 of locking portion 212 illustrated in FIG. 3.

At this time, pressing portion 72 of leaf spring 7 presses upper flange 45 of pressing member 4 downward. As described above, since pressing surface 42 is parallel to the surface of inspection object S, leaf spring 7 presses the surface of inspection object S vertically downward via pressing member 4.

In this way, pressing member 4 is brought by the pressing force through opening-closing part 3A and leaf spring 7 into a state in which the surface of inspection object S is pressed downward in the perpendicular direction.

As described above, in the present embodiment, pressed portion 323 (pressed surface 324), which is a portion pressed by the operator or the device in the operation of closing opening-closing part 3A, is located on the first direction side of latch 5.

That is, such a position of pressed portion 323 (pressed surface 324) (hereinafter, referred to as “pressed position during socket closure”) is farther from pressing center O of a press of inspection object S by pressing member 4 than the position of a press by the operator during closure of the socket with the conventional structure is.

In other words, in case that support shaft 22 serves as a fulcrum, pressing center O serves as an action point, and the pressed position during socket closure serves as a force point, the distance between the force point and the action point in inspection socket 1A of the present embodiment is greater than the distance between the force point and the action point in the socket with the conventional structure.

Therefore, when closing inspection socket 1A according to the present embodiment, the operator or device can close the socket with a force smaller than the force for pressing the pressed position downward when closing the socket with the conventional construction.

Further, in the present embodiment, holding member 6 holds pressing member 4 such that the pressing member can be spaced apart from the holding member except at the time of pressing. Therefore, when pressing member 4 comes into contact with inspection object S, pressing member 4 tilts, and pressing surface 42 and the surface of inspection object S become parallel to each other.

As a result, when inspection object S is pressed, pressing member 4 can be pressed downward in the vertical direction with respect to the surface of inspection object S. Therefore, it is possible to prevent scratches on the surface of inspection object S due to lateral displacement of inspection object S.

Further, in the case of the present embodiment, leaf spring 7 presses pressing member 4. Therefore, by changing the material and thickness of leaf spring 7, the pressing condition can be set only by deflection of leaf spring 7. Therefore, the pressing force acting on pressing member 4 from leaf spring 7 can be easily changed to a desired value.

Further, in the case of the present embodiment, pressing portion 72 of leaf spring 7 presses the middle of upper flange 45. Therefore, independently of the inclination and shape of pressing member 4, leaf spring 7 can press pressing member 4.

Further, in the inspection socket as described in PTL 1, the pressing member is attached by press-fit of the shaft in the side surface of the cover member. Accordingly, the following problems are caused.

(1) Machining the shaft is costly.

(2) Lateral hole machining for fixing the shaft in the pressing member is always necessary and is costly.

(3) Since the shaft is press-fitted into the pressing member, there is a possibility that when the shaft comes off, the shaft drops on the wiring board and the wiring board is short-circuited.

(4) Since the cover member supports the shaft swingably, the cover member needs some thickness for supporting the shaft. When the pressing member also serves as a function of a heat sink, the thickness of the cover member around the pressing member causes a significant decrease in heat dissipation performance of the pressing member.

(5) The shaft does not have other functions than fixation with respect to the pressing member.

In the present embodiment, holding member 6 described above is used instead of the shaft. Thus, the problems (1) to (5) described above can be solved.

Specifically, inspection socket 1A does not include the shaft included in the inspection socket disclosed in PTL 1. Therefore, it becomes unnecessary to form a hole for the shaft in pressing member 4. It is thus possible to reduce the manufacturing cost of pressing member 4.

Further, since the shaft is not included, it is possible to reduce the thickness of opening-closing part 3A. In case that the pressing member also serves as a function of the heat sink, it is possible to achieve more efficient heat dissipation.

In addition, since holding member 6 is formed by press working, the manufacturing cost of holding member 6 can be greatly reduced.

Further, holding member 6 is disposed in first opening portion 34 in opening-closing part 3A. Therefore, even if holding member 6 is disengaged from support shaft 22, the area in which holding member 6 drops is inside inspection socket 1A, but not on the wiring board. Therefore, there is no possibility that the wiring board is short-circuited due to the drop of holding member 6.

In addition, since holding member 6 is formed by press working, the shape of holding member 6 can be easily changed. Holding member 6 can be applied to inspection objects S with various sizes by exchanging the holding member correspondingly to the size of inspection object S.

Note that all the above embodiments are merely illustrative of embodiments in practicing the present invention, and the technical scope of the present invention should not be construed as being limited thereto. That is, the present invention can be embodied in various forms without departing from the spirit, scope, or principal features of the present invention.

The disclosure of Japanese Patent Application No. 2019-217025 dated Nov. 29, 2019 including the specification, drawings and abstract is incorporated herein by reference in its entirety.

### INDUSTRIAL APPLICABILITY

The present invention is preferably applied to a socket for inspecting an electronic component.

### REFERENCE SIGNS LIST

1A Inspection socket
2A Base
21 Body
211 Shaft supporting portion
212 Locking portion
213 Inclined surface
214 Locking surface
22 Support shaft
23 Biasing member
24 Recess
25 Contact portion
3A Opening-closing part
31, 31A, 31B Opening-closing-part main body
31a Cover
311 First frame element
312 Second frame element
313 Third frame element
314 Fourth frame element
31f First end portion
31s Second end portion
32a, 32a1, 32a2 Extension portion
321, 321A First arm portion
322, 322A Second arm portion
323, 323A, 323B Pressed portion
324, 324A, 324B Pressed surface
32 Supported portion
33 Latch support plate
34 First opening portion
35 Holding plate
351 Holding groove
352 First holding portion
353 Second holding portion
354 Base portion
37 Second opening portion
4 Pressing member
41 Pressing-member main body
42 Pressing surface
43 Lower flange
44 Vertical wall portion
45 Upper flange
46 Upper fin
47 Side fin
5 Latch
6 Holding member
61 Holding-member main body
62 Supported portion
63 Supporting portion
631 Protrusion
632 Accommodation groove
64 Held portion
7 Leaf spring
71 Fixation portion
72 Pressing portion
F Pressing direction
S Inspection object

1. A socket, comprising:
an accommodation part including a recess capable of accommodating an electronic component;
an opening-closing part that opens and closes an opening portion of the recess; and
a pivot supporting part that supports the opening-closing part such that the opening-closing part is capable of pivotal movement between an open state and a closed state, wherein
the opening-closing part includes:
a cover that is supported at a first end portion by the pivot supporting part and that extends from the first end portion toward a first direction that is perpendicular to a pivotal axis direction of the pivotal movement and is away from the pivot supporting part in the closed state of the opening-closing part,
a pressing portion that is disposed on the first direction side of the first end portion and is configured to press the electronic component in the recess in the closed state of the opening-closing part, and
a lock portion that is disposed on the first direction side of the pressing portion and is configured to lock the cover to the accommodation part in the closed state of the opening-closing part, and
a pressed portion having a pressed surface and disposed at a position farther from the pivot supporting part than the lock portion is from the pivot supporting part, such that the pressed portion is capable of pivotal movement together with the cover.

2. The socket according to claim 1, wherein the pressed surface is coplanar with an upper surface of the cover.

3. The socket according to claim 1, wherein the pressed surface is located below an upper surface of the cover.

4. The socket according to claim 1, wherein the pressed surface is located above an upper surface of the cover.

5. The socket according to claim 1, wherein
the pressed portion is connected to the cover by a pair of arm portions and a connection portion, the pair of arm portions being disposed to be spaced apart from each other in the pivotal axis direction and extending in the first direction from an end portion of the cover in the first direction, the connection portion connecting the pair of arm portions to each other in the pivotal axis direction.

6. The socket according to claim 1, wherein
the pressed portion is integrally molded with the cover.

7. The socket according to claim 1, wherein
the pressed portion is a separate member from the cover and is joined to the cover by a fastening member.

8. The socket according to claim 1, wherein
the pressed surface protrudes beyond the accommodation part toward the first direction side.

9. The socket according to claim 1, wherein
a distance by which the opening-closing part protrudes beyond the accommodation part in the first direction in the closed state of the opening-closing part is equal to or less than a distance by which the opening-closing part protrudes beyond the accommodation part in a second direction in the open state of the opening-closing part, the second direction being a direction opposite to the first direction.

10. The socket according to claim 1, wherein
a circle centered on a center line that passes through a pressing center of the pressing portion and is parallel to a vertical direction continuously passes on the pressed surface from a first end portion to a second end portion of the pressed surface in the pivotal axis direction.

11. An inspection socket for use in inspection of an electrical characteristic of an electronic component, the inspection socket comprising:
the socket according to claim 1; and
a contact portion disposed on a bottom of the recess and configured to be electrically connected with the electronic component in the recess.
